(19) United States
(12) Patent Application Publication
(10) Pub. No.: US 2025/0171886 A1
(43) Pub. Date: May 29, 2025

(54) YTTRIUM-BASED PROTECTIVE FILM, METHOD FOR PRODUCING SAME, AND MEMBER

(71) Applicants: AGC Inc., Tokyo (JP); TSUBASA SCIENCE CORPORATION, Yokohama-shi (JP)

(72) Inventors: Shuhei OGAWA, Tokyo (JP); Tomonori OGAWA, Tokyo (JP); Michio ISHIKAWA, Yokohama-shi (JP); Michio TANIMURA, Yokohama-shi (JP); Hidekazu OKADA, Yokohama-shi (JP)

(73) Assignees: AGC Inc., Tokyo (JP); TSUBASA SCIENCE CORPORATION, Yokohama-shi (JP)

(21) Appl. No.: 19/038,795

(22) Filed: Jan. 28, 2025

Related U.S. Application Data
(63) Continuation of application No. PCT/JP2023/022986, filed on Jun. 21, 2023.

(30) Foreign Application Priority Data
Aug. 19, 2022 (JP) 2022-131021
Nov. 1, 2022 (JP) 2022-175428

(51) Int. Cl. C23C 14/08; C23C 14/22; C23C 14/28; H01J 37/32; H01L 21/687

(52) U.S. Cl. CPC C23C 14/08; C23C 14/221; C23C 14/28; H01J 37/32495; H01L 21/68757

(57) ABSTRACT

Provided is an yttrium-based protective film which is excellent in plasma resistance and appearance. An yttrium-based protective film containing yttrium oxide is provided, wherein the yttrium-based protective film has a porosity of less than 0.5 vol % and a Vickers hardness of at least 800 HV. This yttrium-based protective film preferably has a thickness of at least 0.3 μm, a crystallite size of at most 40 nm, a Y₂O₃ (222) plane orientation of at least 50%, a hydrogen atom number of at most 5.0×10²¹ atoms/cm³ and a compressive stress of 100 to 1700 MPa.

This application is a continuation of PCT Application No. PCT/JP2023/022986, filed on Jun. 21, 2023, which is based upon and claims the benefit of priority from Japanese Patent Application No. 2022-131021 filed on Aug. 19, 2022 and Japanese Patent Application No. 2022-175428 filed on Nov. 1, 2022. The contents of those applications are incorporated herein by reference in their entireties.

### TECHNICAL FIELD

The present invention relates to an yttrium-based protective film, a production method thereof and a member.

### BACKGROUND ART

The manufacturing of semiconductor devices includes, for example, performing fine processing on a surface of a silicon substrate (silicon wafer) by dry etching with plasma of halogen gas in a chamber and cleaning, with plasma of oxygen gas, the inside of the chamber from which the semiconductor substrate has been taken out after the dry etching.

In the above process, any member exposed to plasma inside the chamber may be corroded, and the corroded part may fall off in the form of particles from the corroded member. The fall-off particles can adhere to the semiconductor substrate and become foreign substances that cause defects in circuit.

Hence, as protective films for protecting such a member exposed to plasma, protective films containing yttrium oxide (Y₂O₃) (also called yttrium-based protective films) are conventionally known.

Patent Document 1 discloses a sprayed coating containing yttrium oxide, which is formed by spraying.

### PRIOR ART DOCUMENTS

### Patent Documents

Patent Document 1: JP-A-2018-76546

### DISCLOSURE OF INVENTION

### Technical Problem

The present inventors have made studies and found that conventional yttrium-based protective films may not have sufficient plasma resistance (resistance to corrosion by plasma).

Further, yttrium-based protective films may have appearance defects (for examples, cracks or wrinkles may occur in yttrium-based protective films). In this case, depending on the intended uses and purposes, it is not suitable to use such yttrium-based protective films as they are.

The present invention has been made in view of the foregoing. It is an object of the present invention to provide an yttrium-based protective film which is excellent in plasma resistance and appearance.

### Solution to Problem

As a result of intensive studies, the present inventors have found that the above object can be achieved by the following configurations, and thus have arrived at the present invention.

In other words, the present invention provides the following [1] to [22].
[1] An yttrium-based protective film comprising yttrium oxide, wherein the yttrium-based protective film has a porosity of less than 0.5 vol % and a Vickers hardness of at least 800 HV.
[2] The yttrium-based protective film according to [1], wherein the thickness of the yttrium-based protective film is at least 0.3 μm.
[3] The yttrium-based protective film according to [1] or [2], wherein the thickness of the yttrium-based protective film is at most 15 μm.
[4] The yttrium-based protective film according to any one of [1] to [3], wherein the crystallite size of the yttrium-based protective film is at most 40 nm.
[5] The yttrium-based protective film according to any one of [1] to [4], wherein the crystallite size of the yttrium-based protective film is at least 6 nm.
[6] The yttrium-based protective film according to any one of [1] to [5], wherein the orientation of the (222) plane of Y₂O₃ is at least 50%.
[7] The yttrium-based protective film according to any one of [1] to [6], wherein the number of hydrogen atoms in the yttrium-based protective film is at most 5.0×10²¹ atoms/cm³.
[8] The yttrium-based protective film according to any one of [1] to [7], wherein the yttrium-based protective film has a compressive stress of 100 to 1700 MPa.
[9] A member comprising a substrate and an yttrium-based protective film as defined in any one of [1] to [8] provided on a film formation surface that is a surface of the substrate.
[10] The member according to [9], wherein the substrate is made of at least one selected from the group consisting of carbon, ceramic and metal, wherein the ceramic is at least one selected from the group consisting of glass, quartz, aluminum oxide, aluminum nitride, cordierite, yttrium oxide, silicon carbide, Si-impregnated silicon carbide, silicon nitride, sialon and aluminum oxynitride, and wherein the metal is at least one selected from the group consisting of aluminum and aluminum-containing alloys.
[11] The member according to [9], wherein the substrate is made of aluminum oxide.
[12] The member according to [9], wherein the substrate is made of quartz.
[13] The member according to any one of [9] to [12], wherein the surface roughness of the film formation surface is less than 1.0 μm in terms of arithmetic mean roughness Ra.
[14] The member according to any one of [9] to [13], wherein the surface roughness of the film formation surface is at least 0.01 μm in terms of arithmetic mean roughness Ra.
[15] The member according to any one of [9] to [14], wherein the maximum length of the film formation surface is at least 30 mm.
[16] The member according to any one of [9] to [15], comprising at least one base layer between the substrate and the yttrium-based protective film, wherein the base layer contains at least one oxide selected from the group consisting of Al₂O₃, SiO₂, Y₂O₃, MgO, ZrO₂, La₂O₃, Nd₂O₃, Yb₂O₃, Eu₂O₃ and Gd₂O₃.
[17] The member according to [16], comprising a plurality of the base layers between the substrate and the yttrium-based protective film, wherein the oxides contained in adjacent ones of the base layers are different from each other.
[18] The member according to any one of [9] to [17], wherein the film formation surface of the substrate includes a first film formation surface defining the maximum length and a second film formation surface different from the first film formation surface, wherein the angle between the first film formation surface and the second film formation surface is 20° to 120°, and wherein the ratio of an area of the second film formation surface to the total area of the film formation surface is at most 60%.
[19] The member according to any one of [9] to [18], wherein the member is for use in a plasma etching apparatus or a plasma CVD apparatus.
[20] A method for producing an yttrium-based protective film as defined in any one of [1] to [8], comprising, in a vacuum, evaporating and depositing an evaporation source onto a substrate under irradiation with ions of at least one element selected from oxygen, argon, neon, krypton and xenon, wherein Y₂O₃ is used as the evaporation source.
[21] The method for producing an yttrium-based protective film according to [20], comprising heating the substrate at 300° C. or higher before the deposition of the evaporation source onto the substrate.
[22] The method for producing an yttrium-based protective film according to or [21], comprising forming at least one base layer on a surface of the substrate before the deposition of the evaporation source onto the substrate, wherein the base layer contains at least one oxide selected from the group consisting of Al₂O₃, SiO₂, Y₂O₃, MgO, ZrO₂, La₂O₃, Nd₂O₃, Yb₂O₃, Eu₂O₃ and Gd₂O₃.

### Advantageous Effects of Invention

According to the present invention, it is possible to provide an yttrium-based protective film which is excellent in plasma resistance and appearance.

### BRIEF DESCRIPTION OF DRAWINGS

FIG. 1 is a schematic view illustrating an example of a member.

FIG. 2 is a schematic view illustrating a ring-shaped substrate in a half cutaway state.

FIG. 3 is a schematic view illustrating a part of a cross section of another ring-shaped substrate.

FIG. 4 is a schematic view illustrating a part of a cross section of still another ring-shaped substrate.

FIG. 5 is a schematic view illustrating an apparatus used for production of an yttrium-based protective film.

FIG. 6 is an XRD pattern of an yttrium-based protective film of Ex. 1.

FIG. 7 is a surface SEM image of the yttrium-based protective film of Ex. 1.

FIG. 8 is a cross-sectional SEM image of the yttrium-based protective film of Ex. 1.

### DESCRIPTION OF EMBODIMENTS

The meanings of terms in the present invention are as follows.

A numerical range expressed using “to” means a range including numerical values described before and after “to” as the lower and upper limits.

### Yttrium-Based Protective Film

An yttrium-based protective film of the present embodiment contains yttrium oxide and has a porosity of less than 0.5 vol % and a Vickers hardness of at least 800 HV.

Hereinafter, an yttrium-based protective film may be simply referred to as a “protective film”, and the yttrium-based protective film (protective film) of the present embodiment may also be referred to as the “present protective film”.

The present protective film is excellent in plasma resistance and appearance.

In the following, the present protective film will be described in detail.

### Vickers Hardness

For excellent plasma resistance of the present protective film, the Vickers hardness of the present protective film is at least 800 HV, preferably at least 1000 HV, still more preferably at least 1100 HV, yet more preferably at least 1200 HV, particularly preferably at least 1250 HV, most preferably at least 1300 HV.

On the other hand, the Vickers hardness of the present protective film is, for example, at most 1800 HV, and is preferably at most 1600 HV.

In order to achieve the above-mentioned range of Vickers hardness, it is preferable to produce the protective film by the method described later (present production method).

The Vickers hardness of the protective film is determined according to JIS Z2244.

More specifically, the Vickers hardness of the protective film is a Vickers hardness (HV 0.005) measured with a micro Vickers hardness testing machine (HM-220, manufactured by Mitutoyo Corporation) under the application of a testing force of 0.049 N by a diamond indenter with an opposite face angle of 136°.

### Porosity

For excellent plasma resistance and appearance of the present protective film, the porosity of the present protective film is less than 0.5 vol %, preferably at most 0.3 vol %, more preferably at most 0.2 vol %, still more preferably at most 0.1 vol %.

In order to achieve the above-mentioned range of porosity, it is preferable to produce the protective film by the method described later (present production method).

The porosity of the protective film is obtained as follows.

Using a focused ion beam (FIB), slope cutting is performed on the protective film and a part of the later described substrate at an angle of 52° in the thickness direction from a surface of the protective film toward the substrate such that a cross section is exposed. The exposed cross section is observed with a field emission scanning electron microscope (FE-SEM) at a magnification of 20000 times, thereby taking a cross-sectional image.

The cross-sectional images are taken at a plurality of locations. More specifically, for example, in the case where the protective film and the substrate are circular in shape, the cross-sectional images are taken at total five locations, one of which is the center of the surface of the protective film (or the surface of the substrate) and four of which are positions 10 mm away from the outer circumference; and the size of the cross-sectional image is set to 6 μm×5 μm. In the case where the thickness of the protective film is at least 5 μm, the cross-sectional images are respectively taken at a plurality of locations such that the cross section of the protective film can be entirely observed in the thickness direction.

Subsequently, the obtained cross-sectional images are analyzed by an image analysis software (ImageJ, manufactured by National Institute of Health) to specify the area of pores in the cross-sectional images. The ratio of the area of the pores to the total cross-sectional area of the protective film is calculated and taken as the porosity (unit: vol %) of the protective film. Herein, the area of fine pores undetectable by the image analysis software (pores with a pore size of at most 20 nm) is regarded as 0.

### Composition

The present protective film contains yttrium oxide (Y₂O₃). The Y₂O₃ content of the present protective film is preferably at least 95 mass %, more preferably at least 98 mass %, still more preferably 100 mass %.

The protective film produced by the method described later (present production method) consists essentially of Y₂O₃ and thus has a Y₂O₃ content falling within the above-mentioned range.

### Orientation

In the case where the protective film is increased in area, it is preferable that the orientation of the (222) plane of Y₂O₃ (hereinafter also simply referred to as “orientation”) in the protective film is higher, from the viewpoint of suppressing the occurrence of cracks (including wrinkles; the same applies to the following) in the protective film.

To be more specific, the orientation is preferably at least 50%, more preferably at least 65%, still more preferably at least 80%.

In order to achieve the above-mentioned range of orientation, it is preferable to produce the protective film by the method described later (present production method).

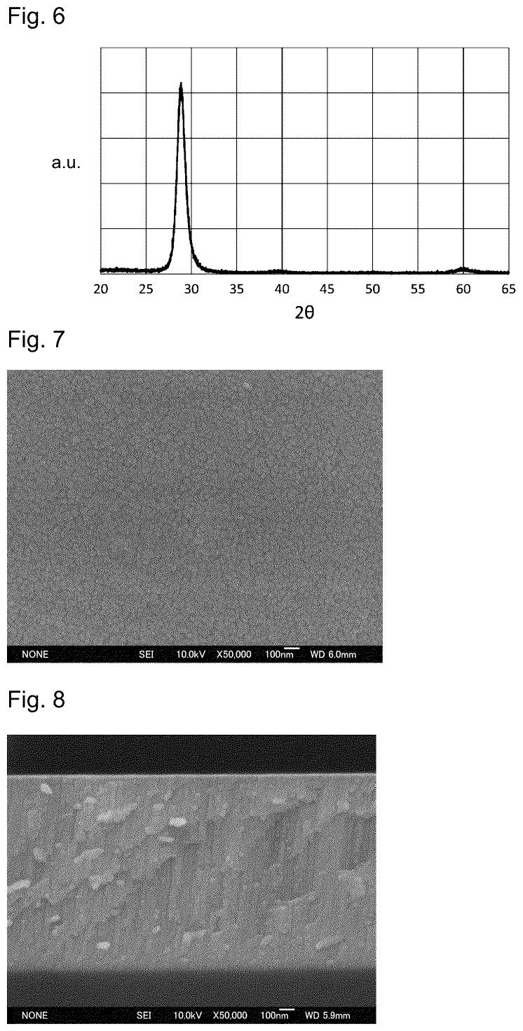

The orientation is the rate (unit: %) of a peak intensity of the (222) plane in an XRD pattern (see FIG. 6) of the protective film, assuming that the total peak intensity of respective faces of Y₂O₃ is 100.

An XRD pattern of the protective film is obtained by conducting XRD measurement with an X-ray diffractometer (D8 Discover Plus, manufactured by Bruker Corporation) in a micro 2D (two-dimensional) mode under the following conditions.
X-ray source: CuKα ray (output: 45 kV, current: 120 mA)
Scanning range: 2θ=10° to 80°
Step time: 0.2 s/step
Scanning speed: 10°/min
Step size: 0.02°
Detector: multi-mode detector EIGER (2D mode)
Primary optical system: multilayer mirror +1.0 mmφ micro slit +1.0 mmφ collimator
Secondary optical system: OPEN

### Crystallite Size

As described above, for example, particles falling off from a member exposed to plasma can adhere to a semiconductor substrate and become foreign substances that cause defects in circuit.

The occurrence of such defects is more suppressed as the size of the particles is decreased.

Thus, the crystallite size of the present protective film is preferably at most 40 nm, more preferably at most 30 nm, still more preferably at most 20 nm, yet more preferably at most 15 nm, particularly preferably at most 11 nm, more particularly preferably at most 10 nm, especially preferably at most 9 nm, most preferably at most 8 nm.

On the other hand, the crystallite size of the present protective film is preferably at least 2 nm, more preferably at least 6 nm, still more preferably at least 7 nm.

In order to achieve the above-mentioned range of crystallite size, it is preferable to produce the protective film by the mention described later (present production method).

The crystallite size of the protective film is determined according to the Scherrer equation based on XRD pattern data obtained by XRD measurement of the mirror polished protective film.

### Thickness

The thickness of the present protective film is, for example, at least 0.3 μm, and is preferably at least 1.0 μm, more preferably at least 1.5 μm, still more preferably at least 5 μm, particularly preferably at least 10 μm, most preferably at least 15 μm.

On the other hand, the thickness of the present protective film is, for example, at most 300 μm, and is preferably at most 200 μm, more preferably at most 100 μm, still more preferably at most 50 μm, particularly preferably at most 30 μm. The thickness of the present protective film may be at most 10 μm.

The thickness of the protective film is measured as follows.

A cross section of the protective film is observed with a scanning electron microscope (SEM) to measure the thickness of the protective film at arbitrary five locations. The average of these five measurements is taken as the thickness (unit: μm) of the protective film.

### Number of Hydrogen Atoms

It is preferable that the number of hydrogen atoms in the present protective film is small. In this case, the present protective film is more excellent in plasma resistance.

The reason for this is assumed as follows. Hydrogen, when contained in a large amount in the protective film, easily reacts with fluorine in plasma (or gas used for generation of plasma) whereby the protective film is susceptible to damage. On the other hand, when the protective film contains less hydrogen, the reaction of hydrogen and fluorine is relatively reduced whereby damage of the protective film is suppressed.

To be more specific, the number of hydrogen atoms in the present protective film (intra-film hydrogen atom number) is preferably at most 5.0×10²¹ atoms/cm³, more preferably at most 4.5×10²¹ atoms/cm³, still more preferably at most 3.5×10²¹ atoms/cm³, yet more preferably at most 3.0×10²¹ atoms/cm³, particularly preferably at most 2.5×10²¹ atoms/cm³, most preferably at most 2.3×10²¹ atoms/cm³.

Here, hydrogen in the protective film is most likely due to the influence of moisture in the substrate as described later.

Especially in the case where the material of the substrate is ceramic, the protective film can be formed with a reduced number of hydrogen atoms by heating (preheating) the substrate to before the formation of the protective film.

Other methods for reducing the number of hydrogen atoms in the protective film will be described later.

On the other hand, the number of hydrogen atoms in the present protective film is preferably at least 0.1×10²¹ atoms/cm³, more preferably at least 0.5×10²¹ atoms/cm³.

The number of hydrogen atoms in the protective film is determined with the use of a secondary ion mass spectrometer (model: IMS-6f, manufactured by AMETEK Inc.) under the conditions that: the primary ion species is Cs⁺; the primary acceleration voltage is 15.0 KV; the detection area is 8 μmφ; and the measurement depth is 500 nm.

### Compressive Stress

Stress (internal stress, residual stress) in the present protective film is preferably compressive stress rather than tensile stress.

The compressive stress in the present protective film is preferably at least 100 MPa, more preferably at least 200 MPa, still more preferably at least 300 MPa.

On the other hand, the compressive stress in the present protective film is preferably at most 1700 MPa, more preferably at most 1600 MPa, still more preferably at most 1500 MPa.

The compressive stress in the protective film is determined as follows.

A protective film is formed on a substrate of quartz. The surface shape of the formed protective film is measured with a surface contour measuring instrument (SURFCOM NEX 241 SD2-13, manufactured by Tokyo Seimitsu Co., Ltd), and the compressive stress in the protective film (film stress σ) is determined according to the Stoney equation (following equation).

The Stoney equation is expressed as follows.

σ=Yd²/6(1−v)t×8h/c²+4h2

In the above equation, σ is the film stress; Y is the Young's modulus of the substrate; d is the thickness of the substrate; v is the Poisson's ratio of the substrate; t is the thickness of the protective film; h is the amount of warpage; and c is the radius of curvature.

### Member

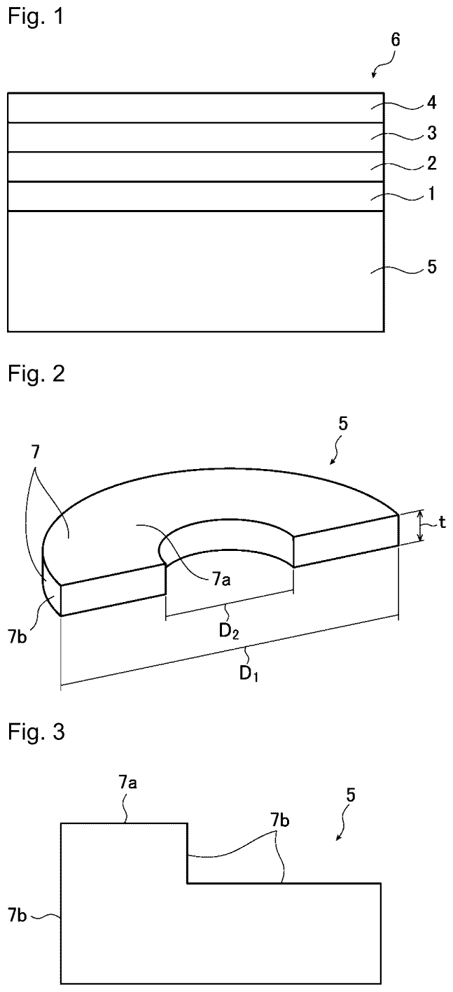

FIG. 1 is a schematic view illustrating an example of a member 6.

The member 6 has a substrate 5 and an yttrium-based protective film 4.

As shown in FIG. 1, a base layer (a base layer 1, a base layer 2 and a base layer 3) may be arranged between the substrate 5 and the yttrium-based protective film 4. The base layer is however not limited to these three layers.

The member of the present embodiment (hereinafter also referred to as the “present member”) includes the above-described present protective film as the yttrium-based protective film.

The present member, which has a surface covered by the present protective film is excellent in plasma resistance as in the present protective film.

In the following, the respective parts of the present member will be described in detail.

### Substrate

The substrate has at least a surface on which the yttrium-based protective film (or the base layer described later) is to be formed. This surface may be hereinafter referred to as a “film formation surface” for convenience.

### Material

The material of the substrate is selected as appropriate depending on the intended use and the like of the member.

For example, the substrate is made of at least one material selected from the group consisting of carbon (C), ceramic and metal.

Here, the ceramic is, for example, at least one selected from the group consisting of glass (such as soda-lime glass or the like), quartz, aluminum oxide (Al₂O₃), aluminum nitride (AlN), cordierite, yttrium oxide, silicon carbide (SiC), Si-impregnated silicon carbide, silicon nitride (SiN), sialon and aluminum oxynitride (AlON).

The Si-impregnated silicon carbide is obtained by heating and melting elemental Si and impregnating silicon carbide (SiC) with the molten Si.

The metal is, for example, at least one selected from the group consisting of aluminum (Al) and alloys containing aluminum (Al).

### Shape

The shape of the substrate is not particularly limited and can be, for example, a flat plate shape, a ring shape, a dome shape, a concave shape or a convex shape. The shape of the substrate is selected as appropriate depending on the intended use and the like of the member.

### Surface Roughness of Film Formation Surface

From the reasons described later, the surface roughness of the film formation surface of the substrate in terms of arithmetic mean roughness Ra is preferably less than 1.0 μm, more preferably at most 0.6 μm, still more preferably at most 0.3 μm, yet more preferably at most 0.1 μm, particularly preferably at most 0.08 μm, more particularly preferably at most 0.05 μm, especially preferably at most 0.01 μm, most preferably at most 0.005 μm.

On the other hand, the surface roughness of the film formation surface of the substrate in terms of arithmetic mean roughness Ra is preferably at least 0.01 μm, more preferably at least 0.05 μm, still more preferably at least 0.1 μm.

The surface roughness (arithmetic mean roughness Ra) of the film formation surface is measured according to JIS B0601: 2001.

### Maximum Length of Film Formation Surface

The maximum length of the film formation surface of the substrate is preferably at least 30 mm, more preferably at least 100 mm, still more preferably at least 200 mm, yet more preferably at least 300 mm, particularly preferably at least 500 mm, more particularly preferably at least 800 mm, most preferably at least 1000 mm.

Here, the maximum length refers to the longest dimension of the film formation surface. More specifically, for example, in the case where the film formation surface has a circular shape in plan view, the diameter of the circular shape is taken as the maximum length. In the case where the film formation surface has a ring shape in plan view, the outer diameter of the ring shape is taken as the maximum length. In the case where the film formation surface has a quadrilateral shape in plan view, the length of the longest diagonal line of the quadrilateral shape is taken as the maximum length.

On the other hand, the maximum length of the film formation surface is, for example, at most 2000 mm, and is preferably at most 1500 mm.

FIG. 2 is a schematic view illustrating the ring-shaped substrate 5 in a half cutaway state.

For example, in the case where the substrate 5 shown in FIG. 2 has an outer diameter D₁ of 100 mm, an inner diameter D₂ of 90 mm and a thickness t of 5 mm, the maximum length of the substrate is 100 mm.

The substrate 5 has a film formation surface 7 which may include a first film formation surface 7a defining the maximum length (outer diameter D₁) and a second film formation surface 7b different from the first film formation surface 7a as shown in FIG. 2.

The ratio of an area of the second film formation surface 7b to the total area of the film formation surface 7 is, for example, at most 60%.

FIG. 3 is a schematic view illustrating a part of a cross section of another ring-shaped substrate 5.

The substrate 5 may have a plurality of second film formation surfaces 7b as shown in FIG. 3.

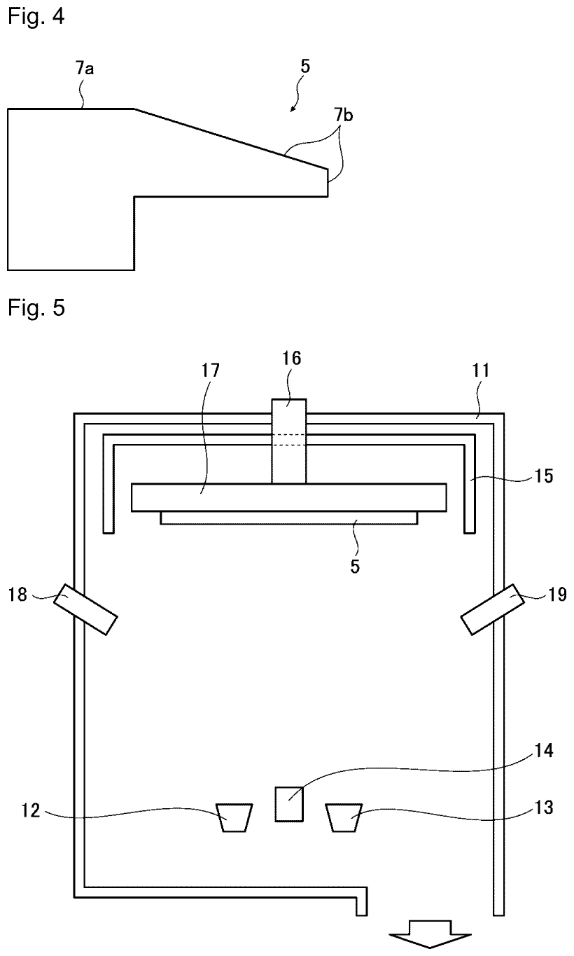

FIG. 4 is a schematic view illustrating a part of a cross section of still another ring-shaped substrate 5.

The angle between the first film formation surface 7a and the second film formation surface 7b is, for example, 20° to 120°. In the substrate 5 shown in FIG. 4, the angle between the first film formation surface 7a and the second film formation surface 7b connected to the first film formation surface 7a is about 30°.

### Base Layer

As described above, at least one base layer may be arranged between the substrate and the yttrium-based protective film.

The formation of the base layer leads to development of compressive stress with relief of tensile stress in the yttrium-based protective film, or leads to improved adhesion of the yttrium-based protective film to the substrate.

The upper limit of the number of base layers is not particularly limited, and is preferably at most 5, more preferably at most 4, still more preferably at most 3, particularly preferably at most 2, most preferably 1.

The base layer is preferably in the form of an amorphous film or a microcrystalline film.

The base layer preferably contains at least one oxide selected from the group consisting of Al₂O₃, SiO₂, Y₂O₃, MgO, ZrO₂, La₂O₃, Nd₂O₃, Yb₂O₃, Eu₂O₃ and Gd₂O₃.

In the case where a plurality of base layers are arranged between the substrate and the yttrium-based protective film, it is preferable that the oxides contained in the adjacent base layers are different from each other.

More specifically, as an example of the case where the oxides contained in the adjacent base layers are different from each other, there may be mentioned a case where the oxide of the base layer 1 is “SiO₂”, the oxide of the base layer 2 is “Al₂O₃ +SiO₂” and the oxide of the base layer 3 is “Al₂O₃”.

The thickness of the base layer is preferably at least 0.1 μm, more preferably at least 0.4 μm, still more preferably at least 0.8 μm.

On the other hand, the thickness of the base layer is, for example, at most 15 μm, and is preferably at most 10 μm, more preferably at most 7 μm, still more preferably at most 3 μm.

The thickness of the base layer is measured in the same manner as the thickness of the yttrium-based protective film.

### Use of Member

The present member is used, for example, as a top plate or the other member in a semiconductor device manufacturing apparatus (a plasma etching apparatus, a plasma CVD apparatus or the like).

The use of the present member is however not limited to the above.

### Production Method of Yttrium-Based Protective Film and Member

Next, a method for producing the yttrium-based protective film of the present embodiment (also referred to as “present production method”) will be described below. The present production method is also a method for producing the present member described above.

The present production method is a so-called ion-assisted deposition (IAD) method.

In general, the yttrium-based protective film containing Y₂O₃ is produced by, in a vacuum, evaporating and depositing an evaporation source (Y₂O₃) onto the substrate under irradiation with ions.

According to the present production method, the yttrium-based protective film can be obtained in very dense form. In other words, the obtained yttrium-based protective film is low in porosity. Further, the obtained protective film is small in crystallite size.

By the way, an yttrium-based protective film is more susceptible to cracks as the thickness of the yttrium-based protective film is increased.

Further, the area of an yttrium-based protective film formed on the film formation surface is increased as the area of the film formation surface is increased. In this case, the yttrium-based protective film is also susceptible to cracks.

According to the present production method, however, the dense and hard yttrium-based protective film is obtained.

Furthermore, tensile stress in the yttrium-based protective film is relieved when the base layer is formed.

The yttrium-based protective film obtained by the present production method is thus less susceptible to cracks even when increased in thickness or increased in area.

Moreover, the surface roughness (arithmetic mean roughness Ra) of the film formation surface of the substrate is preferably in the above-mentioned range. With this, the yttrium-based protective film is obtained in denser and harder form and is less susceptible to cracks.

It is herein noted that, in an yttrium-based protective film obtained by a spraying method, an aerosol deposition (AD) method, an ion plating (IP) method or the like, many pores tend to remain.

### Apparatus Configuration

The present production method will be described in more detail below with reference to FIG. 5.

FIG. 5 is a schematic view illustrating an apparatus used for production of the yttrium-based protective film.

The apparatus shown in FIG. 5 has a chamber 11. The inside of the chamber 11 can be evacuated to a vacuum by driving a vacuum pump (not shown).

In the chamber 11, a crucible 12, a crucible 13 and an ion gun 14 are provided, above which a holder 17 is provided.

The holder 17 is formed integral with a support shaft 16 and is rotated by rotation of the support shaft 16. A heater 15 is disposed around the holder 17.

The above-described substrate 5 is held to the holder 17 with the film formation surface thereof facing down. The substrate 5 held to the holder 17 is rotated by rotation of the holder 17 while being heated by the heater 15.

Further, a crystal-type film thickness monitor 18 and a crystal-type film thickness monitor 19 are attached to the chamber 11.

### Formation of Yttrium-Based Protective Film

The formation of the yttrium-based protective film (not shown in FIG. 5) on the substrate 5 in the apparatus of FIG. 5 will be now described below.

First, the evaporation source Y₂O₃ is charged into either one or both of the crucibles 12 and 13.

After the substrate 5 is held to the holder 17, the inside of the chamber 11 is evacuated to a vacuum.

The holder 11 is then rotated while driving the heater 15. Thus, the substrate 5 is rotated while heated.

In this state, ion-assisted deposition is performed for film formation on the substrate 5.

In other words, the evaporation source Y₂O₃ charged in either one or both of the crucibles 12 and 13 is evaporated while being irradiated with ions (an ion beam) from the ion gun 14.

The ions emitted from the ion gun 14 are preferably ions of at least one element selected from the group consisting of oxygen, argon, neon, krypton and xenon.

The evaporation source is melted and evaporated by irradiation with an electron beam (not shown).

By deposition of the evaporated evaporation source onto the substrate 5 (film formation surface), the yttrium-based protective film is formed.

### Pressure Inside Chamber

The film formation is carried out in a vacuum. To be more specific, the pressure inside the chamber 11 is preferably at most 6×10⁻² Pa, more preferably at most 5×10⁻² Pa, still more preferably at most 3×10⁻² Pa.

On the other hand, the pressure inside the chamber 11 is preferably more than 1×10⁻⁶ Pa, more preferably at least 1×10⁻⁵ Pa, still more preferably at least 1×10⁻⁴ Pa.

### Temperature of Substrate

During the film formation, the temperature of the substrate 5 heated by the heater 15 is preferably at least 200° C., more preferably at least 250° C.

On the other hand, this temperature is preferably at most 400° C., more preferably at most 350° C.

### Deposition Rate

Using the crystal-type film thickness monitors 18 and 19, the rate of film formation by evaporation of the evaporation source in the crucibles 12 and 13 (deposition rate) is respectively monitored in advance.

The deposition rate is adjusted by controlling the conditions of the electron beam emitted to the evaporation source and the conditions (current value, current density etc.) of the ion beam from the ion gun 14.

During the formation of the yttrium-based protective film, the deposition rate (unit: nm/min) of each evaporation source is adjusted to a desired value.

The deposition rate of the evaporation source Y₂O₃ is preferably at least 1 nm/min, more preferably at least 1.5 nm/min, still more preferably at least 2 nm/min.

The deposition rate of the evaporation source Y₂O₃ is preferably at most 20 nm/min, more preferably at most 15 nm/min, still more preferably at most 10 nm/min.

### Conditions of Ion Irradiation

The distance between the ion gun 14 and the substrate 5 is preferably at least 700 mm, more preferably at least 900 mm. On the other hand, this distance is preferably at most 1500 mm, more preferably at most 1300 mm.

The current value of the ion beam is preferably at least 1000 mA, more preferably at least 1500 mA. On the other hand, the current value of the ion beam is preferably at most 3000 mA, more preferably at most 2500 mA.

The current density of the ion beam is preferably at least 40 μA/cm², more preferably at least 65 μA/cm², still more preferably at least 75 μA/cm², particularly preferably at least 77 μA/cm², for higher hardness of the obtained yttrium-based protective film.

On the other hand, the current density of the ion beam is preferably at most 140 μA/cm², more preferably at most 120 μA/cm², still more preferably at most 100 μA/cm².

### Formation of Base Layer

Before the formation of the yttrium-based protective film, it is preferable to form the above-describe base layer (for example, base layer 1, base layer 2 and base layer 3) on the film formation surface of the substrate 5.

The base layer is formed by ion-assisted deposition as in the formation of the yttrium-based protective film.

For example, in the case where the base layer is formed of Al₂O₃, Al₂O₃ is charged as the evaporation source in either one or both of the crucibles 12 and 13, and under irradiation with ions (an ion beam) from the ion gun 14, the evaporation source is evaporated and deposited onto the film formation surface of the substrate 5.

The conditions of formation of the base layer conform to the conditions of formation of the yttrium-based protective film.

By the way, the substrate may contain crystallization water.

For example, in the case where the temperature of a substrate of aluminum oxide (Al₂O₃) is raised from room temperature, the occurrence of crystallization water derived from hydrates, that is, low-temperature stable phases of aluminum oxide (e.g. boehmite and γ-alumina) is observed at around 520° C.

When moisture due to crystallization water of the substrate is contained in the yttrium-based protective film, the number of hydrogen atoms in the yttrium-based protective film is easily increased.

Hence, the base layer is formed on the film formation surface of the substrate before the deposition of the evaporation source Y₂O₃ onto the film formation surface of the substrate (that is, before the formation of the yttrium-based protective film).

This is preferable in that, since at least the film formation surface of the substrate is covered, crystallization water in the substrate is unlikely to be contained in the yttrium-based protective film and, by extension, the number of hydrogen atoms in the yttrium-based protective film is reduced.

### Preheating of substrate

As is the formation of the base layer, it is preferable to heat (preheat) the substrate at high temperature before the deposition of the evaporation source Y₂O₃ onto the film formation surface of the substrate (that is, the formation of the yttrium-based protective film) from the reason that crystallization water in the substrate is unlikely to be contained in the yttrium-based protective film.

The preheating temperature is preferably at least 300° C., more preferably at least 400° C., still more preferably at least 450° C., particularly preferably at least 500° C. On the other hand, the preheating temperature is, for example, at most 800° C., and is preferably at most 750° C., more preferably at most 700° C.

The preheating time is preferably at least 60 minutes, more preferably at least 120 minutes, still more preferably at least 240 minutes, particularly preferably at least 480 minutes.

On the other hand, the preheating time is preferably at most 1200 minutes, more preferably at most 1000 minutes, still more preferably at most 800 minutes, particularly preferably at most 600 minutes.

The preheating atmosphere is, for example, an atmosphere of air.

### EXAMPLES

The present invention will be now described in further detail with reference to Examples. It should however be understood that the present invention is by no means restricted to the following Examples.

Here, Ex. 1 to Ex. 27, Ex. 30 to Ex. 31 and Ex. 39 to Ex. 42 correspond to Examples of the present invention; Ex. 28 to Ex. 29, Ex. 32 to Ex. 33 and Ex. 37 to Ex. 38 correspond to Comparative Examples; and Ex. 34 to Ex. 36 correspond to Reference Examples.

### Ex. 1

Using the apparatus described with reference to FIG. 5, an yttrium-based protective film (protective film) was produced under the conditions shown in Table 1 below.

As a substrate, used was a circular substrate (thickness: 10 mm) made of aluminum oxide (Al₂O₃) and having a film formation surface with a diameter (maximum length) shown in Table 1.

This substrate was preheated in an air atmosphere in a state of being held to the holder in the chamber. The preheating temperature was set to a temperature shown in Table 1; and the preheating time was set to 600 minutes. In the case where the substrate was not preheated, “-” is indicated in the column of the preheating time in the table.

Next, under the production conditions shown in Table 1, a base layer and an yttrium-based protective film (protective film) as shown in Table 1 were formed on the film formation surface of the substrate.

As the production conditions not shown in Table 1, a beam of oxygen (O) ions was emitted from the ion gun; the distance between the ion gun and the substrate was set to 1100 mm; and the current value of the ion beam was set to 2000 mA.

FIG. 6 is an XRD pattern of the yttrium-based protective film of Ex. 1.

In the yttrium-based protective film of Ex. 1, the (222) plane, which is the close-packed plane of the cubic crystal system, was preferentially oriented at about 28° as is seen in FIG. 6.

The yttrium-based protective film of Ex. 1 was observed with a SEM at a magnification of 50000 times.

FIG. 7 is a surface SEM image of the yttrium-based protective film of Ex. 1. FIG. 8 is a cross-sectional SEM image of the yttrium-based protective film of Ex. 1.

It is seen from FIGS. 7 and 8 that the yttrium-based protective film of Ex. 1 was very dense and was excellent in smoothness. It is further seen that the yttrium-based protective film of Ex. 1 was uniform in particle size.

### Ex. 2 to Ex. 33

In Ex. 2 to Ex. 33, yttrium-based protective films (protective films) were produced in the same manner as in Ex. 1, except that one or more conditions were changed from those in Ex. 1.

For example, the outline of the changes is as follows. In each Ex., there may be other changes from Ex. 1 in addition to the following changes.

In Ex. 2, the current density of the ion beam was changed from that in Ex. 1.

In Ex. 3 to Ex. 6, the number and/or composition of base layers was changed from those in Ex. 1.

In Ex. 7 to Ex. 10, no base layer was formed.

In Ex. 11 to Ex. 20, the substrate and/or base layer was changed from those in Ex. 1.

Here, the substrate (glass) used in Ex. 13 was of commercially available soda-lime glass

In Ex. 15, the substrate used was of single crystal aluminum; and one surface of the substrate was alumite-treated and polished to form a Al₂O₃ layer as the base layer. This base layer is indicated as “alumite layer” in Table 1.

In Ex. 16, the substrate used was of aluminum; and one surface of the substrate was anodized with oxalic acid to form a Al₂O₃ layer as the base layer. This base layer was indicated as “anodized layer” in Table 1.

In Ex. 21 to Ex. 22, the thickness of the protective film was changed from that in Ex. 1.

In Ex. 23 to Ex. 24, the area of the film formation surface was changed from that in Ex. 1.

In Ex. 25 to Ex. 29, the pressure inside the chamber was changed from that in Ex. 1. Here, the protective film of Ex. 28 was amorphous (thus, “-” is indicated in the column of the “orientation” in the table).

In Ex. 30 to Ex. 31, the deposition rate was changed from that in Ex. 1.

In Ex. 32 to Ex. 33, the surface roughness (Ra) of the film formation surface was changed from that in Ex. 1.

### Ex. 34 to Ex. 36

In Ex. 34, a protective film of sapphire was used.

In Ex. 35, a protective film of metal aluminum was used.

In Ex. 36, a protective film of quartz was used.

### Ex. 37 to Ex. 38

In Ex. 37, a protective film of Y₂O₃ was formed by an IP method rather than by an IAD method.

In Ex. 38, a protective film of Y₂O₃ was formed by a CVD method rather than by an IAD method.

### Ex. 39 to Ex. 42

In Ex. 39 to Ex. 42, protective films were produced in the same manner as in Ex. 7, Ex. 1, Ex. 3 and Ex. 26, respectively, except that the substrate was not preheated.

### Properties of Protective Films

For the protective film of each Ex., the number of hydrogen atoms, Vickers hardness, porosity, crystallite size, orientation, thickness and compressive stress were determined by the above-described methods. The results are shown in Table 1.

Here, the value of the compressive stress is expressed in minus.

### Etching Amount

The protective film of each Ex. was subjected to ion etching and/or radical etching and evaluated for plasma resistance.

More specifically, a 10 mm×5 mm surface of the protective film was mirror polished, and a part of the mirror polished surface (referred to as “test surface”) was masked with a Kapton tape.

Subsequently, a test (exposure test) was conducted with a CCP-type plasma etching apparatus in which: plasma was generated by inducing a discharge in gas described below under the conditions of a pressure of 10 Pa and an RF power of 600 W; and the test surface was exposed to the generated plasma.

In the ion etching, discharge (plasma generation) was induced using CF₄ gas (flow rate: 100 sccm) and O₂ gas (flow rate: 100 sccm) so that ions of CF₄ were generated in the plasma.

In the radical etching, discharge (plasma generation) was induced using CF₄ gas (flow rate: 100 sccm), Ar gas (flow rate: 50 sccm) and O₂ gas (flow rate: 100 sccm) so that radicals of F were generated in the plasma.

By repeating 15 minutes of discharge (plasma generation) five times, the exposure test was conducted for total 150 minutes. In this way, the non-masked part of the test surface was subjected to etching.

After that, a step formed between the masked part and the non-masked part of the test surface was measured with a stylus surface profiler (Dectak 150, manufactured by ULVAC, Inc.) to determine the amount of etching. The results are shown in Table 1.

In Table 1, “-” is indicated in the case where ion etching or radical etching was not conducted.

The smaller the etching amount (unit: nm), the more excellent the plasma resistance.

To be more specific, the plasma resistance can be evaluated as excellent when the etching amount (ion etching amount, radical etching amount) is at most 200 nm.

### Appearance

The appearance of the formed protective film was visually checked to confirm the occurrence or non-occurrence of cracks (including wrinkles; the same applies to the following).

In Table 1, “cracks” is indicated when cracks of 1.0 mm or more occurred; “slight cracks” is indicated when cracks of less than 1.0 mm occurred; and “no cracks” is indicated when no cracks occurred. The appearance can be evaluated as excellent in the case of “slight cracks” or “no cracks”.

In the case of “slight cracks”, no cracks occurred in the center portion of the protective film even though fine cracks occurred in the edge surface of the protective film.

TABLE 1
(Part 1)

| | | | Ex. 1 | Ex. 2 | Ex. 3 | Ex. 4 | Ex. 5 | Ex. 6 | Ex. 7 |
|---|---|---|---|---|---|---|---|---|---|
| Production | Pressure [Pa] inside chamber | | 1 × 10⁻² | 1 × 10⁻² | 1 × 10⁻² | 1 × 10⁻² | 1 × 10⁻² | 1 × 10⁻² | 1 × 10⁻² |
| conditions | Temperature [° C.] of Substrate | | 300 | 300 | 300 | 300 | 300 | 300 | 300 |
| | Y₂O₃ | Deposition rate [nm/min] | 3.42 | 3.42 | 3.42 | 3.42 | 3.42 | 3.42 | 3.42 |
| | | of evaporation source | | | | | | | |
| | Ion beam current density [μA/cm²] | | 80 | 70 | 80 | 80 | 80 | 80 | 80 |
| Substrate | Material | | Al₂O₃ | Al₂O₃ | Al₂O₃ | Al₂O₃ | Al₂O₃ | Al₂O₃ | Al₂O₃ |
| | Preheating temperature[° C.] | | 550 | 550 | 550 | 550 | 550 | 550 | 550 |
| | Film | Ra [μm] | 0.02 | 0.02 | 0.02 | 0.02 | 0.02 | 0.02 | 0.02 |
| | formation | Area [cm²] | 314.2 | 314.2 | 314.2 | 314.2 | 314.2 | 314.2 | 314.2 |
| | surface | Maximum length [mm] | 200 | 200 | 200 | 200 | 200 | 200 | 200 |
| Base layer | 1 | Composition | Al₂O₃ | Al₂O₃ | SiO₂ | SiO₂ | SiO₂ | SiO₂ | — |
| | | Thickness [μm] | 1 | 1 | 0.5 | 0.5 | 0.5 | 0.5 | — |
| | 2 | Composition | — | — | Al₂O₃ + | Al₂O₃ + | ZrO₂ | MgO | — |
| | | | | | SiO₂ | SiO₂ | | | |
| | | Thickness [μm] | — | — | 1 | 1 | 1 | 1 | — |
| | 3 | Composition | — | — | — | Al₂O₃ | Al₂O₃ | Al₂O₃ | — |
| | | Thickness [μm] | — | — | — | 1 | 1 | 1 | — |
| Protective | Number [×10²¹ atoms/cm³] of | | 1.9 | 2.0 | 1.9 | 1.8 | 2.1 | 2.1 | 2.8 |
| film | hydrogen atoms | | | | | | | | |
| | Vickers hardness [HV] | | 1482 | 902 | 1481 | 1322 | 1324 | 1326 | 1453 |
| | Porosity [vol %] | | 0.04 | 0.28 | 0 | 0.06 | 0.05 | 0.07 | 0.41 |
| | Crystallite size [nm] | | 7.9 | 5.2 | 8.3 | 8.2 | 8.8 | 8.4 | 8.3 |
| | Orientation [%] | | 90.8 | 90.9 | 91.4 | 92.1 | 90.2 | 90.4 | 87.4 |
| | Thickness [μm] | | 15.3 | 10.6 | 15.3 | 15.4 | 15.4 | 15.2 | 13.3 |
| | Compressive stress [MPa] | | −1244 | −942 | −1246 | −1241 | −1240 | −1233 | −1152 |
| | Ion etching amount [nm] | | 73 | 126 | 73 | 72 | 74 | 75 | 115 |
| | Radical etching amount [nm] | | — | — | — | — | — | — | — |
| | Appearance | | no | no | no | no | no | no | no |
| | | | cracks | cracks | cracks | cracks | cracks | cracks | cracks |
| | | | Ex. 8 | Ex. 9 | Ex. 10 | Ex. 11 | Ex. 12 | Ex. 13 | Ex. 14 |
| Production | Pressure [Pa] inside chamber | | 1 × 10⁻² | 1 × 10⁻² | 1 × 10⁻² | 1 × 10⁻² | 1 × 10⁻² | 1 × 10⁻² | 1 × 10⁻² |
| conditions | Temperature [° C.] of Substrate | | 300 | 300 | 300 | 300 | 300 | 270 | 300 |
| | Y₂O₃ | Deposition rate [nm/min] | 3.42 | 3.42 | 3.42 | 3.42 | 6.78 | 3.42 | 3.42 |
| | | of evaporation source | | | | | | | |
| | Ion beam current density [μA/cm²] | | 80 | 80 | 80 | 80 | 80 | 80 | 80 |
| Substrate | Material | | Al₂O₃ | Al₂O₃ | Al₂O₃ | Quartz | Quartz | Glass | Al |
| | Preheating temperature[° C.] | | 550 | 550 | 550 | 550 | 550 | 550 | 550 |
| | Film | Ra [μm] | 0.05 | 0.22 | 0.5 | 0.02 | 0.02 | 0.02 | 0.09 |
| | formation | Area [cm²] | 314.2 | 314.2 | 314.2 | 314.2 | 314.2 | 314.2 | 314.2 |
| | surface | Maximum length [mm] | 200 | 200 | 200 | 200 | 200 | 200 | 200 |
| Base layer | 1 | Composition | — | — | — | SiO₂ | SiO₂ | SiO₂ | Al₂O₃ |
| | | Thickness [μm] | — | — | — | 0.5 | 0.5 | 0.5 | 1 |
| | 2 | Composition | — | — | — | Al₂O₃ + | Al₂O₃ + | Al₂O₃ + | — |
| | | | | | | SiO₂ | SiO₂ | SiO₂ | |
| | | Thickness [μm] | — | — | — | 1 | 1 | 1 | — |
| | 3 | Composition | — | — | — | — | — | Al₂O₃ | — |
| | | Thickness [μm] | — | — | — | — | — | 1 | — |

| | | | | | | | | |
|---|---|---|---|---|---|---|---|---|
| Protective | Number [×10²¹ atoms/cm³] of | 2.6 | 2.8 | 2.6 | 1.5 | 1.7 | 1.6 | 2.1 |
| film | hydrogen atoms | | | | | | | |
| | Vickers hardness [HV] | 1426 | 1233 | 852 | 1412 | 873 | 1022 | 982 |
| | Porosity [vol %] | 0.01 | 0.19 | 0.49 | 0.01 | 0.23 | 0 | 0.16 |
| | Crystallite size [nm] | 10.5 | 11.3 | 11.2 | 9.1 | 9.6 | 12.2 | 11.9 |
| | Orientation [%] | 84.6 | 66.8 | 50.9 | 90.7 | 88.6 | 92.2 | 80.4 |
| | Thickness [μm] | 15.2 | 0.9 | 12.8 | 10.5 | 10.4 | 15.5 | 4.4 |
| | Compressive stress [MPa] | −1171 | −1127 | −1085 | −1213 | −749 | −767 | −1043 |
| | Ion etching amount [nm] | 122 | 186 | 193 | 72 | 87 | 85 | 97 |
| | Radical etching amount [nm] | — | — | — | — | — | — | — |
| | Appearance | no | no | no | no | no | no | no |

| | | | | | | |
|---|---|---|---|---|---|---|
| cracks | cracks | cracks | cracks | cracks | cracks | cracks |

TABLE 1
(Part 2)

| | | | Ex. 15 | Ex. 16 | Ex. 17 | Ex. 18 | Ex. 19 | Ex. 20 | Ex. 21 |
|---|---|---|---|---|---|---|---|---|---|
| Production | Pressure [Pa] inside chamber | | 1 × 10⁻² | 1 × 10⁻² | 1 × 10⁻² | 1 × 10⁻² | 1 × 10⁻² | 1 × 10⁻² | 1 × 10⁻² |
| conditions | Temperature [° C.] of Substrate | | 300 | 300 | 300 | 300 | 300 | 300 | 300 |
| | Y₂O₃ | Deposition rate [nm/min] | 2.1 | 3.42 | 2.1 | 2.1 | 2.1 | 2.1 | 2.1 |
| | | of evaporation source | | | | | | | |
| | Ion beam current density [μA/cm²] | | 80 | 80 | 80 | 80 | 80 | 80 | 80 |
| Substrate | Material | | Al | Al | AlN | AlN | AlN | Cordierite | Al₂O₃ |
| | Preheating temperature[° C.] | | 550 | 550 | 550 | 550 | 550 | 550 | 550 |
| | Film | Ra [μm] | 0.03 | 0.09 | 0.03 | 0.05 | 0.1 | 0.02 | 0.02 |
| | formation | Area [cm²] | 314.2 | 314.2 | 314.2 | 314.2 | 314.2 | 9503.0 | 314.2 |
| | surface | Maximum length [mm] | 200 | 200 | 200 | 200 | 200 | 1100 | 200 |
| Base layer | 1 | Composition | Alumite | Anodized | Al₂O₃ | Al₂O₃ | Al₂O₃ | Al₂O₃ | Al₂O₃ |
| | | | layer | layer | | | | | |
| | | Thickness [μm] | 1 | 1 | 1 | 1 | 1 | 1 | 1 |
| | 2 | Composition | — | Al₂O₃ | — | — | — | — | — |
| | | Thickness [μm] | — | 1 | — | — | — | — | — |
| | 3 | Composition | — | — | — | — | — | — | — |
| | | Thickness [μm] | — | — | — | — | — | — | — |
| Protective | Number [×10²¹ atoms/cm³] of | | 2.1 | 2.2 | 2.0 | 2.0 | 2.0 | 0.2 | 0.8 |
| film | hydrogen atoms | | | | | | | | |
| | Vickers hardness [HV] | | 1322 | 1187 | 1267 | 1234 | 1189 | 1326 | 1330 |
| | Porosity [vol %] | | 0.05 | 0.33 | 0.05 | 0.11 | 0.18 | 0.05 | 0.08 |
| | Crystallite size [nm] | | 8.8 | 13.6 | 12.3 | 12.1 | 12.4 | 8.8 | 18.2 |
| | Orientation [%] | | 88.2 | 79.6 | 84.9 | 80.1 | 74.8 | 84.8 | 82.7 |
| | Thickness [μm] | | 15.2 | 11.1 | 10.3 | 10.2 | 10.3 | 15.3 | 204.1 |
| | Compressive stress [MPa] | | −1216 | −1173 | −1091 | −1044 | −1032 | −1211 | −1442 |
| | Ion etching amount [nm] | | 77 | 83 | 69 | 69 | 73 | 75 | 65 |
| | Radical etching amount [nm] | | — | — | 95 | 97 | 102 | 94 | 97 |
| | Appearance | | no | no | no | no | no | no | no |
| | | | cracks | cracks | cracks | cracks | cracks | cracks | cracks |
| | | | Ex. 22 | Ex. 23 | Ex. 24 | Ex. 25 | Ex. 26 | Ex. 27 | Ex. 28 |
| Production | Pressure [Pa] inside chamber | | 1 × 10⁻² | 1 × 10⁻² | 1 × 10⁻² | 1 × 10⁻³ | 1 × 10⁻⁴ | 1 × 10⁻⁵ | 1 × 10⁻⁶ |
| conditions | Temperature [° C.] of Substrate | | 300 | 300 | 300 | 300 | 300 | 300 | 300 |
| | Y₂O₃ | Deposition rate [nm/min] | 2.1 | 2.1 | 2.1 | 1.9 | 2.1 | 2.5 | 4.0 |
| | | of evaporation source | | | | | | | |
| | Ion beam current density [μA/cm²] | | 80 | 80 | 80 | 80 | 80 | 78 | 75 |
| Substrate | Material | | Al₂O₃ | Al₂O₃ | Al₂O₃ | Al₂O₃ | Al₂O₃ | Al₂O₃ | Al₂O₃ |
| | Preheating temperature[° C.] | | 550 | 550 | 550 | 550 | 550 | 550 | 550 |
| | Film | Ra [μm] | 0.02 | 0.02 | 0.02 | 0.11 | 0.11 | 0.19 | 0.02 |
| | formation | Area [cm²] | 314.2 | 17670.9 | 9503.0 | 314.2 | 314.2 | 314.2 | 314.2 |
| | surface | Maximum length [mm] | 200 | 1500 | 1100 | 200 | 200 | 200 | 200 |
| Base layer | 1 | Composition | SiO₂ | Al₂O₃ | — | Al₂O₃ | — | Al₂O₃ | Al₂O₃ |
| | | Thickness [μm] | 1 | 1 | — | 1 | — | 1 | 1 |
| | 2 | Composition | Al₂O₃ + | — | — | — | — | — | — |
| | | | SiO₂ | | | | | | |
| | | Thickness [μm] | — | — | — | — | — | — | — |
| | 3 | Composition | — | — | — | — | — | — | — |
| | | Thickness [μm] | — | — | — | — | — | — | — |

| | | | | | | | | |
|---|---|---|---|---|---|---|---|---|
| Protective | Number [×10²¹ atoms/cm³] of | 2.1 | 2.1 | 2.6 | 1.2 | 2.6 | 1.5 | 2.2 |
| film | hydrogen atoms | | | | | | | |
| | Vickers hardness [HV] | 1222 | 1315 | 1283 | 1250 | 1310 | 1364 | 420 |
| | Porosity [vol %] | 0.07 | 0.18 | 0.44 | 0.06 | 0.05 | 0.05 | 0 |
| | Crystallite size [nm] | 7.8 | 12.1 | 8.8 | 8.8 | 12 | 14 | 7.9 |
| | Orientation [%] | 95.2 | 88.9 | 87.9 | 78.4 | 77.5 | 67.3 | — |
| | Thickness [μm] | 1.4 | 10.4 | 10.4 | 15.2 | 15.2 | 15.4 | 12.4 |
| | Compressive stress [MPa] | −1034 | −1275 | −1422 | −1275 | −1688 | −1620 | −411 |
| | Ion etching amount [nm] | 70 | 66 | 103 | 71 | 106 | 69 | 234 |
| | Radical etching amount [nm] | 94 | 97 | 121 | 82 | 89 | 86 | — |
| | Appearance | no | no | slight | no | no | no | cracks |

| | | | | | |
|---|---|---|---|---|---|
| cracks | cracks | cracks | cracks | cracks | cracks |

TABLE 1
(Part 3)

| | | | Ex. 29 | Ex. 30 | Ex. 31 | Ex. 32 | Ex. 33 | Ex. 34 | Ex. 35 |
|---|---|---|---|---|---|---|---|---|---|
| Production | Pressure [Pa] inside chamber | | 7 × 10⁻² | 1 × 10⁻² | 1 × 10⁻³ | 1 × 10⁻⁴ | 1 × 10⁻⁵ | — | — |
| conditions | Temperature [° C.] of Substrate | | 300 | 300 | 300 | 300 | 300 | — | — |
| | Y₂O₃ | Deposition rate [nm/min] | 2.1 | 3.6 | 1.9 | 2.1 | 2.1 | — | — |
| | | of evaporation source | | | | | | | |
| | Ion beam current density [μA/cm²] | | 70 | 80 | 80 | 85 | 80 | — | — |
| Substrate | Material | | Al₂O₃ | Al₂O₃ | Al₂O₃ | Al₂O₃ | Al₂O₃ | — | — |
| | Preheating temperature[° C.] | | 550 | 550 | 550 | 550 | 550 | — | — |
| | Film | Ra [μm] | 0.02 | 0.11 | 0.11 | 1.0 | 1.5 | — | 0.091 |
| | formation | Area [cm²] | 314.2 | 314.2 | 314.2 | 314.2 | 314.2 | 314.2 | 314.2 |
| | surface | Maximum length [mm] | 200 | 200 | 200 | 200 | 200 | 200 | 200 |
| Base layer | 1 | Composition | Al₂O₃ | Al₂O₃ | Al₂O₃ | Al₂O₃ | Al₂O₃ | — | — |
| | | Thickness [μm] | 1 | 1 | 1 | 1 | 1 | — | — |
| | 2 | Composition | — | — | — | — | — | — | — |
| | | Thickness [μm] | — | — | — | — | — | — | — |
| | 3 | Composition | — | — | — | — | — | — | — |
| | | Thickness [μm] | — | — | — | — | — | — | — |

| | | | | | | | | |
|---|---|---|---|---|---|---|---|---|
| Protective | Number [×10²¹ atoms/cm³] of | 3.0 | 2.4 | 1.9 | 2.2 | 2.1 | — | — |
| film | hydrogen atoms | | | | | | | |
| | Vickers hardness [HV] | 685 | 1145 | 1288 | 494 | 494 | — | — |
| | Porosity [vol %] | 1.2 | 0.05 | 0.05 | 1.57 | 1.57 | 0 | 0 |
| | Crystallite size [nm] | 10 | 8.8 | 8.8 | 11.2 | 11.8 | — | — |
| | Orientation [%] | 67.2 | 75.6 | 77.3 | 33.1 | 23.8 | — | — |
| | Thickness [μm] | 18.5 | 14.3 | 14.6 | 12.2 | 12.2 | — | — |
| | Compressive stress [MPa] | −587 | −412 | −1591 | −1547 | −1682 | — | — |
| | Ion etching amount [nm] | 224 | 99 | 97 | 135 | 168 | 781 | 845 |
| | Radical etching amount [nm] | — | — | — | — | — | — | — |
| | Appearance | no | no | slight | cracks | cracks | — | — |

| | | |
|---|---|---|
| cracks | cracks | cracks |

| | | | Ex. 36 | Ex. 37 | Ex. 38 | Ex. 39 | Ex. 40 | Ex. 41 | Ex. 42 |
|---|---|---|---|---|---|---|---|---|---|
| Production | Pressure [Pa] inside chamber | | — | — | — | 1 × 10⁻² | 1 × 10⁻² | 1 × 10⁻² | 1 × 10⁻⁴ |
| conditions | Temperature [° C.] of Substrate | | — | — | — | 300 | 300 | 300 | 300 |
| | Y₂O₃ | Deposition rate [nm/min] | — | — | — | 3.42 | 3.42 | 3.42 | 2.1 |
| | | of evaporation source | | | | | | | |
| | Ion beam current density [μA/cm²] | | — | — | — | 80 | 80 | 80 | 80 |
| Substrate | Material | | — | Al₂O₃ | Quartz | Al₂O₃ | Al₂O₃ | Al₂O₃ | Al₂O₃ |
| | Preheating temperature[° C.] | | — | 550 | 550 | — | — | — | — |
| | Film | Ra [μm] | — | 0.02 | 0.02 | 0.02 | 0.02 | 0.02 | 0.11 |
| | formation | Area [cm²] | 314.2 | 314.2 | 314.2 | 314.2 | 314.2 | 314.2 | 314.2 |
| | surface | Maximum length [mm] | 200 | 200 | 200 | 200 | 200 | 200 | 200 |
| Base layer | 1 | Composition | — | — | — | — | Al₂O₃ | SiO₂ | — |
| | | Thickness [μm] | — | — | — | — | 1 | 0.5 | — |
| | 2 | Composition | — | — | — | — | — | Al₂O₃ + | — |
| | | | | | | | | SiO₂ | |
| | | Thickness [μm] | — | — | — | — | — | 1 | — |
| | 3 | Composition | — | — | — | — | — | — | — |
| | | Thickness [μm] | — | — | — | — | — | — | — |

| | | | | | | | | |
|---|---|---|---|---|---|---|---|---|
| Protective | Number [×10²¹ atoms/cm³] of | — | 5.2 | 6.7 | 4.4 | 3.2 | 3.1 | 3.9 |
| film | hydrogen atoms | | | | | | | |
| | Vickers hardness [HV] | — | 780 | 560 | 1410 | 1432 | 1429 | 1298 |
| | Porosity [vol %] | 0 | 0.21 | 0.87 | 0.38 | 0.09 | 0.08 | 0.09 |
| | Crystallite size [nm] | — | 7.1 | 7.9 | 8.5 | 7.8 | 8.4 | 11.6 |
| | Orientation [%] | — | 48.3 | 55.2 | 86.9 | 90.4 | 91.2 | 77.6 |
| | Thickness [μm] | — | 9.4 | 7.1 | 13.3 | 15.3 | 15.3 | 15.2 |
| | Compressive stress [MPa] | — | −1560 | −569 | −1139 | −1239 | −1244 | −1567 |
| | Ion etching amount [nm] | 1620 | 247 | 256 | 174 | 139 | 131 | 178 |
| | Radical etching amount [nm] | — | — | — | — | — | — | 109 |
| | Appearance | — | no | cracks | no | no | no | no |

| | | | | |
|---|---|---|---|---|
| cracks | cracks | cracks | cracks | cracks |

### Summary of Evaluation Results

As is seen in Table 1, the yttrium-based protective films of Ex. 1 to Ex. 27 and Ex. 30 to Ex. 31 were excellent in plasma resistance and appearance. By contrast, the yttrium-based protective films of Ex. 28 to Ex. 29, Ex. 32 to Ex. 33 and Ex. 37 to Ex. 38 were not sufficient in at least either plasma resistance or appearance.

In the following, some Ex. will be explained below.

Ex. 2: The compressive stress in the protective film was reduced by reduction of the ion beam current density.

Ex. 8 to Ex. 10: As the surface roughness of the film formation surface was increased, the compressive stress in the protective film was reduced.

Ex. 12: By increase of the deposition rate, the effect of ion irradiation was decreased, and the compressive stress in the protective film was reduced.

Ex. 13: This was an example where the substrate of soda-lime glass was used, and the compressive stress in the protective film was reduced by decrease of the substrate temperature.

Ex. 26 to Ex. 27: By reduction of the pressure inside the chamber during the film formation, the kinetic energy caused by collision of the emitted ions and the particles (evaporation source) was increased with increase of mean free path, whereby the compressive stress in the protective film was increased.

Ex. 28: By increase of the deposition rate, the effect of ion irradiation was decreased, and the compressive stress in the protective film was reduced.

Ex. 29: The compressive stress in the protective film was reduced by reduction of the ion beam current density.

Ex. 30: Due to decrease of the evaporation source temperature, the crystal growth became slow, and the compressive stress in the protective film was reduced.

Ex. 31: By reduction of the pressure inside the chamber during the film formation and by decrease of the deposition rate, the effect of ion irradiation was increased, and the compressive stress in the protective film was increased.

Ex. 32 to Ex. 33: By reduction of the pressure inside the chamber during the film formation, the kinetic energy caused by collision of the emitted ions and the particles (evaporation source) was increased with increase of mean free path, whereby the compressive stress in the protective film was increased.

Ex. 39 to Ex. 42: Without preheating of the substrate, the number of hydrogen atoms in the protective film was increased as compared respectively with those in Ex. 7, Ex. 1, Ex. 3 and Ex. 26 in each of which the substrate was preheated.

### REFERENCE SYMBOLS

1, 2, 3: Base layer
4: Yttrium-based protective film
5: Substrate
6: Member
7: Film formation surface
7a: First film formation surface
7b: Second film formation surface
11: Chamber
12, 13: Crucible
14: Ion gun
15: Heater
16: Support shaft
17: Holder
18, 19: Crystal-type film thickness monitor

What is claimed is:

1. An yttrium-based protective film comprising yttrium oxide,
wherein the yttrium-based protective film has a porosity of less than 0.5 vol % and a Vickers hardness of at least 800 HV.

2. The yttrium-based protective film according to claim 1, wherein the thickness of the yttrium-based protective film is at least 0.3 μm.

3. The yttrium-based protective film according to claim 1, wherein the thickness of the yttrium-based protective film is at most 15 μm.

4. The yttrium-based protective film according to claim 1, wherein the crystallite size of the yttrium-based protective film is at most 40 nm.

5. The yttrium-based protective film according to claim 1, wherein the crystallite size of the yttrium-based protective film is at least 6 nm.

6. The yttrium-based protective film according to claim 1, wherein the orientation of the (222) plane of Y₂O₃ is at least 50%.

7. The yttrium-based protective film according to claim 1, wherein the number of hydrogen atoms in the yttrium-based protective film is at most 5.0×10²¹ atoms/cm³.

8. The yttrium-based protective film according to claim 1, wherein the yttrium-based protective film has a compressive stress of 100 to 1700 MPa.

9. A member, comprising:
a substrate; and
an yttrium-based protective film as defined in claim 1 provided on a film formation surface that is a surface of the substrate.

10. The member according to claim 9,
wherein the substrate is made of at least one selected from the group consisting of carbon, ceramic and metal,
wherein the ceramic is at least one selected from the group consisting of glass, quartz, aluminum oxide, aluminum nitride, cordierite, yttrium oxide, silicon carbide, Si-impregnated silicon carbide, silicon nitride, sialon and aluminum oxynitride, and
wherein the metal is at least one selected from the group consisting of aluminum and aluminum-containing alloys.

11. The member according to claim 9, wherein the substrate is made of aluminum oxide.

12. The member according to claim 9, wherein the substrate is made of quartz.

13. The member according to claim 9, wherein the surface roughness of the film formation surface is less than 1.0 μm in terms of arithmetic mean roughness Ra.

14. The member according to claim 9, wherein the surface roughness of the film formation surface is at least 0.01 μm in terms of arithmetic mean roughness Ra.

15. The member according to claim 9, wherein the maximum length of the film formation surface is at least 30 mm.

16. The member according to claim 9, comprising at least one base layer between the substrate and the yttrium-based protective film,
wherein the base layer contains at least one oxide selected from the group consisting of Al₂O₃, SiO₂, Y₂O₃, MgO, ZrO₂, La₂O₃, Nd₂O₃, Yb₂O₃, Eu₂O₃ and Gd₂O₃.

17. The member according to claim 16, comprising a plurality of the base layers between the substrate and the yttrium-based protective film,
wherein the oxides contained in adjacent ones of the base layers are different from each other.

18. The member according to claim 9,
wherein the film formation surface of the substrate includes a first film formation surface defining the maximum length and a second film formation surface different from the first film formation surface,
wherein the angle between the first film formation surface and the second film formation surface is 20° to 120°, and
wherein the ratio of an area of the second film formation surface to the total area of the film formation surface is at most 60%.

19. The member according to claim 9, wherein the member is for use in a plasma etching apparatus or a plasma CVD apparatus.

20. A method for producing an yttrium-based protective film as defined in claim 1, comprising, in a vacuum, evaporating and depositing an evaporation source onto a substrate under irradiation with ions of at least one element selected from oxygen, argon, neon, krypton and xenon,
wherein Y₂O₃ is used as the evaporation source.

21. The method for producing an yttrium-based protective film according to claim 20, comprising heating the substrate at 300° C. or higher before the deposition of the evaporation source onto the substrate.

22. The method for producing an yttrium-based protective film according to claim 20, comprising forming at least one base layer on a surface of the substrate before the deposition of the evaporation source onto the substrate,
wherein the base layer contains at least one oxide selected from the group consisting of Al₂O₃, SiO₂, Y₂O₃, MgO, ZrO₂, La₂O₃, Nd₂O₃, Yb₂O₃, Eu₂O₃ and Gd₂O₃.
